(19) United States
(12) Patent Application Publication
(10) Pub. No.: US 2026/0150256 A1
(43) Pub. Date: May 28, 2026

(54) Display Assembly and Vehicle

(71) Applicant: Motherson Innovations Company Limited, London (GB)

(72) Inventors: Navaneetham Mishra, Stuttgart (DE); Norbert Nemeth, Stuttgart (DE)

(73) Assignee: Motherson Innovations Company Limited, London (GB)

(21) Appl. No.: 19/395,797

(22) Filed: Nov. 20, 2025

(30) Foreign Application Priority Data
Nov. 22, 2024 (DE) 10 2024 134 452.0

(51) Int. Cl. H05K 9/00; B60K 35/22; B60K 35/81; B60R 16/023; B60R 16/033; H05K 5/02; H05K 7/20

(52) U.S. Cl. CPC H05K 9/0054; B60R 16/0231; B60R 16/033; H05K 5/0204; H05K 7/20963; B60K 35/22; B60K 35/81; B60K 2360/33

(57) ABSTRACT

A display assembly for a vehicle includes at least one display unit, at least one back light cover coupled to the display unit, and at least one display holder that can mount the display assembly to the vehicle and at least one printed circuit board. At least one first electromagnetic coupling sealing unit is disposed between the printed circuit board and the back light cover. In certain instances, at least one second electromagnetic coupling sealing unit is disposed between the printed circuit board and the display holder. Further, a vehicle is provided with such a display assembly.

### CROSS-REFERENCE TO RELATED APPLICATIONS

This application claims priority from German Patent Application No. DE102024134452.0, filed Nov. 22, 2024. The disclosure of which is incorporated herein by reference in its entirety.

### BACKGROUND OF THE INVENTION

This invention relates in general to a display assembly for a vehicle having at least one display unit, at least one back light cover coupled to the display unit, at least one display holder that can be mounted to the display assembly, and at least one printed circuit board (PCB). The invention also relates to a vehicle with such a display assembly. Display assemblies are used in a vehicle to display e.g. the surrounding environment of the vehicle. These display assemblies are bulky in size as multiple internal components such as electronic control units (ECUs) are stacked on each other to provide a single display assembly. The ECUs are also placed in different particular housings and in different horizontal planes.

Electromagnetic radiation is generated by electronic components such as ECUs. This electromagnetic radiation creates a lot of performance issues, and this electromagnetic radiation increases significantly when a device has two or more ECUs. Therefore, electromagnetic shields, in particular electromagnetic coupling shields (EMC shields), are also stacked on each other in different horizontal planes in order to minimize electromagnetic interference. The electromagnetic shields add to the number of components of the display assembly and increase the assembly time during manufacture as well as the assembly size.

One such prior art reference, EP 4 164 922 A2, relates to a vehicle display system and a vehicle display retention system. The vehicle display retention system comprises a display unit affixed to a display frame and connected to a grab bar, and an intermediate adapter coupled to the grab bar, wherein the intermediate adapter comprises a mounting arm for attachment to a vehicle at a first mounting member, a retention strap coupled to the mounting arm and the vehicle at the first mounting member, and an attachment component coupled to the intermediate adapter. The control units in this vehicle display have separate housings in different vertical planes and therefore, the vehicle display is bulky and problematic to accommodate inside the vehicle due to space constraints. Additionally, the control units of these vehicle display systems are difficult to get completely EMC-shielded by the EMC shielding units or plates. Thus, there is no complete protection from electrical and magnetic interference. Moreover, the EMC shields are also stacked vertically to make the vehicle display bulkier or thicker.

Another prior art reference, U.S. Pat. No. 10,499,517 B2, relates to a display assembly for an automotive vehicle that includes a housing having a front opening, a peripheral wall, and a rear wall arranged along a main axis. The housing is configured to receive a display module on the front opening side and a printed circuit board connected to the display module. The printed circuit board includes an electronic control unit to control the display module having an internal casing which is mounted in the housing against the housing rear wall, wherein said internal casing comprises a first holding surface configured to receive the printed circuit board and a second holding surface configured to receive the display module. The housing comprises a first set of axially retaining members holding the printed circuit board on the first holding surface and a second set of axially retaining members holding the display module on the second holding surface.

Yet another prior art reference, EP 3 944 010 A1, relates to a display assembly for an imaging device including a display panel, a display, a first control unit, a second control unit and a thermally insulating layer, and a housing. The thermally insulating layer splits the housing in at least a first cavity comprising the first control unit and a second cavity comprising the second control unit. The thermally insulating layer prevents heat generated in the first cavity or the second cavity from reaching the other cavity and comprises an electrically conductive material to at least partially shield electromagnetic radiation generated in the first or the second cavity from reaching the other cavity.

CN 206 031 082 U relates to a full-color screen assembly comprising a front frame, a liquid crystal display, a display bracket, an instrument bracket, a printed circuit board, a speaker and an instrument rear cover, wherein the liquid crystal display is fixed to the display bracket, the display bracket is fixed to the front of the instrument bracket, the liquid crystal display is nested in the front frame, the front frame is fixed to the front of the instrument bracket, the printed circuit board is fixed to the back of the instrument bracket, the speaker is fixed to the inner surface of the rear instrument cover, the rear instrument cover is disposed on the printed circuit board and fixed to the back of the instrument bracket, the display bracket comprises a plurality of reeds arranged around the display bracket, wherein the liquid crystal display is fixed to the display bracket by some of the reeds, and the remaining reeds fix the display bracket to the front of the instrument bracket.

In view of the aforementioned drawbacks, and others found in the existing state of the art, it is the object of the invention to further develop the known display assembly to overcome at least some of the drawbacks of the prior art. In particular it is an object of the invention to provide a display assembly with a compact design, a smaller package with less components and a reduced assembly time. Other objects of the invention are to eliminate:
additional EMC shield elements or materials,
an additional housing to provide an accommodation space for the control unit or display driver board,
additional heat dissipation elements or materials,
additional stress release elements, and/or
additional parts like shields, control unit carrier, additional heat sink, cables and/or contact springs.

This object is solved by the invention disclosed herein and recited in claim 1. Embodiments of the display assembly according to the invention are also described in claims 2 to 14.

### SUMMARY OF THE INVENTION

This invention relates in general to vehicular display assemblies and, in particular, to a display assembly for a vehicle having a display unit, a back light cover coupled to the display unit, a display holder that can be mounted to the display assembly, and at least one PCB.

In an embodiment, a display assembly for a vehicle is provided, the display assembly may comprise a display unit, a back light cover coupled to the display unit, a display holder removably attached to the back light cover, wherein the display holder is configured to hold the display assembly to the vehicle, at least one printed circuit board (PCB) sandwiched between the back light cover and the display holder, and a first EMC sealing unit disposed between the at least one PCB and the back light cover and a second EMC sealing unit disposed between the at least one PCB and the display holder.

In an embodiment, at least one control unit may be disposed on at least one PCB.

In an embodiment, a housing may be provided to at least partially encase the display unit, the back light cover and the at least one PCB.

In an embodiment, a heat sink may be disposed between the at least one PCB and the display holder.

In an embodiment, the back light cover may be configured to provide a first accommodation portion and a second accommodation portion, wherein the first accommodation portion accommodates a first PCB of the at least one PCB and the second accommodation portion accommodates a second PCB of the at least one at least one PCB.

In an embodiment, the first accommodation portion and the second accommodation portion may be positioned substantially lateral to each other to reduce overall thickness of the display assembly, and/or wherein the first control unit and the second control unit may be placed laterally to each other or placed in a horizontal plane (H1) in the first accommodation portion and the second accommodation portion respectively. The back light cover, and the display holder may be made of electrically conductive material and may made by a die casting process.

In an embodiment, the at least two EMC sealing units may be conductive and/or are formed using a fluid-in-place technology.

In an embodiment, the at least two EMC sealing units may be formed using any one of a printing process, a CNC machining process or combination thereof.

According to an embodiment to sandwich an element between two parts is to be understood as being at least partly arranged between two parts, wherein the two parts are optionally located at least partly at opposite sides of the element. The element may be in direct or indirect contact between the two parts.

The present disclosure also provides a vehicle comprising the display assembly as described above.

The present disclosure refers to the display assembly configured with one or more enhanced electromagnetic sealing element/s. Furthermore, the display assembly is reduced in thickness and the display assembly has increased accommodation space to accommodate the electronic components such as electronic control units or display drivers.

The disclosed display assembly uses the housing of the display panel as an accommodation space for the control unit or display driver board. Further, it provides a backlight cover and/or a display adapter with function of EMC shielding and at the same time the display holder is used for heat dissipation. In an embodiment, the EMC shield is provided as fluid-in-place (FIP) sealing unit so that no stress is directly formed on the control units and display panels. The EMC shielding concept is integrated between a display holder or adapter and display back light unit. This helps in reducing additional parts like shields, control unit carrier, additional heat sink, cables and/or contact springs.

It should be understood that any one of the described features and/or embodiments of the disclosure may be used separately or in combination with other disclosed features and/or embodiments. The term “at least one” refers to one or a plurality and may be even understood as “all of”.

Various aspects of this invention will become apparent to those skilled in the art from the following detailed description of the preferred embodiment, when read in light of the accompanying drawings.

### BRIEF DESCRIPTION OF THE DRAWINGS

FIG. 1A is a front view of a vehicle, according to an embodiment of the present disclosure;

FIG. 1B is a top view of the vehicle of FIG. 1A;

FIG. 2 is a perspective view of a display assembly disposed in a dashboard of the vehicle of FIG. 1A;

FIG. 3A is a front view of a display assembly, according to an embodiment of the present disclosure;

FIG. 3B is a cross sectional view of the display assembly of FIG. 3A, taken along a line A-A′ as depicted in FIG. 3A;

FIG. 4 is another cross sectional view of the display assembly of FIG. 3A, taken along a line A-A′ as depicted in FIG. 3;

FIG. 5 is an exploded view from the front side of a display assembly, according to another embodiment of the present disclosure; and

FIG. 6 is an exploded view from the back side of the display assembly of FIG. 5.

The drawings referred to in this description are not to be understood as being drawn to scale except if specifically noted, and such drawings are only exemplary in nature.

### DETAILED DESCRIPTION OF THE PREFERRED EMBODIMENT

In the drawings, the thicknesses of layers and regions may be exaggerated for clarity. When it is indicated that an element or layer is “on” or “above” another element or layer, this comprises a case in which another layer or element is interposed therebetween as well as a case in which the element or layer is directly above the other element or layer. In principle, reference signs designate elements throughout the specification. In the following description, like reference signs are used to designate elements, which have the same function within the same idea illustrated in the drawings of each embodiment of the present disclosure.

When detailed description of known functions or configurations related to the present disclosure is deemed to unnecessarily blur the gist of the disclosure, the detailed description thereof will be omitted. Also, numerals (e.g., first, second, etc.) used in the description herein are merely identifiers for distinguishing one element from another element.

The following detailed description of illustrative embodiments is better understood when read in conjunction with the appended drawings. To illustrate the present disclosure, exemplary constructions of the disclosure are shown in the drawings. However, the present disclosure is not limited to a specific device, or a tool and instrumentalities disclosed herein.

Reference in this specification to “one embodiment” or “an embodiment” means that a particular feature, structure, or characteristic described in connection with the embodiment is included in at least one embodiment of the present disclosure. The appearances of the phrase “in an embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

Moreover, although the following description contains many specifics for the purposes of illustration, anyone skilled in the art will appreciate that many variations and/or alterations to said details are within the scope of the present disclosure. Similarly, although many of the features of the present disclosure are described in terms of each other, or in conjunction with each other, one skilled in the art will appreciate that many of these features can be provided independently of other features. Accordingly, this description of the present disclosure is set forth without any loss of generality to, and without imposing limitations upon, the present disclosure.

In addition, the terms “module” and “unit” used to refer to elements in the following description are given or used in combination only in consideration of ease of writing the specification, and the terms themselves do not have distinct meanings or roles.

Furthermore, the use of a singular term, such as, “a” is not to be interpreted as limiting the number of components or details of components. Additionally, various terms and/or phrases describing or indicating a position or directional reference such as, but not limited to, “top”, “bottom”, “front”, “rear”, “forward”, “rearward”, “end”, “outer”, “inner”, “left”, “right”, “vertical”, “horizontal”, etc. may relate to one or more particular components as seen generally from a user's vantage point during use or operation, and such terms and/or phrases are not to be interpreted as limiting, but merely as a representative basis for describing the disclosure to one skilled in the art. In addition, the suffix “region”, “part”, “unit” for a component used in the following description are given or mixed in consideration of only the ease of writing the specification, and do not have meanings or roles distinguished from each other.

While the present disclosure is illustrated in the context of a four-wheeled vehicle, however, holding structure and aspects and features thereof can be used with other types of vehicles such as a two-wheeled vehicle, three-wheeled vehicle, six-wheeled vehicle, eight-wheeled vehicle, etc. as well. In illustrated embodiments, it is to be noted that terms such as “four-wheeled vehicle” and “vehicle” are interchangeably used throughout the description.

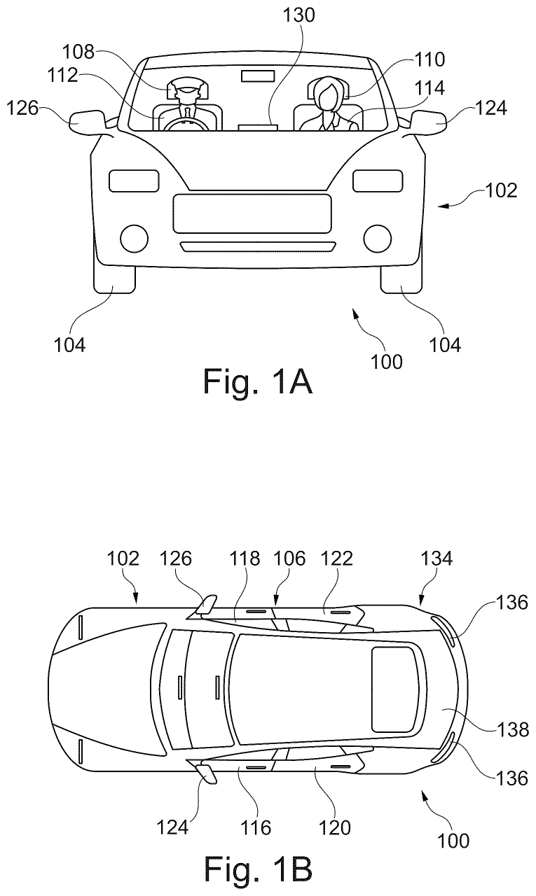

Referring now to the drawings, there is illustrated in FIG. 1A a front view of a vehicle 100 with four wheels 104, in accordance with an embodiment of the present disclosure. FIG. 1B illustrates a top view of the vehicle 100 of FIG. 1A. The vehicle 100 referred to herein embodies a four-wheeled vehicle. Alternatively, the vehicle 100 may embody other vehicles such as two-wheeled vehicles, three-wheeled vehicles, six-wheeled vehicles, eight-wheeled vehicles, all-terrain vehicles (ATVs), etc., without limiting the scope of the disclosure.

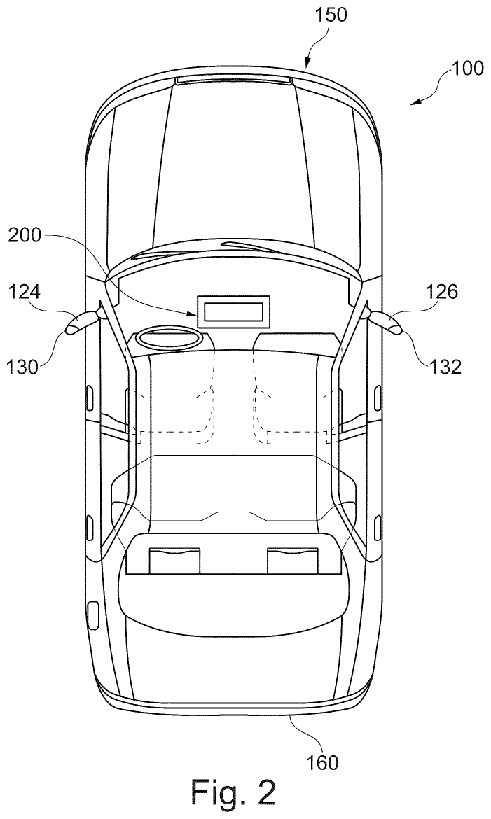

A front portion 102 or rear portion 134 of the vehicle 100 may include a power unit (not shown). The power unit of an internal combustion (IC) engine-based vehicle includes an engine unit and a transmission unit, whereas the power unit of an electrical propulsion-based vehicle includes a motor and a transmission unit. The front portion 102 may also include a bumper 150 and/or a dashboard (refer FIG. 2) as a vehicle interior component. The power unit provides the necessary power for driving the front and/or rear wheels of the vehicle 100. According to the general knowledge of those skilled in the art the front portion 102 and/or rear portion 134 of the vehicle 100 may include the above stated parts and/or other parts.

According to the embodiment of FIGS. 1A and 1B, a middle portion 106 of the vehicle 100 includes a driver seat 108 and at least one passenger seat 110. The driver seat 108 provides seating for a driver 112 and the passenger seat 110 provides seating for a passenger 114. The middle portion 106 of the vehicle 100 further includes a front left side door 116 and a front right side door 118, it may also include a back left side door 120, and a back right side door 122 (shown in FIG. 1B). A left side mirror assembly 124 is coupled to the front left side door 116 and a right side mirror assembly 126 is coupled to the front right side door 118. Each one of the left side mirror assembly 124 and the right side mirror assembly 126 assists the driver 112 in seeing the areas outside a peripheral vision (including i.e., a blind spot). According to various embodiments, the mirror assemblies may comprise at least one mirror and/or at least one image sensing device 130, 132 (shown in FIG. 2).

Furthermore, according to the embodiment of FIG. 1B, the rear portion 134 of the vehicle 100 includes two taillight assemblies 136 and a boot space 138. The boot space 138 allows articles to be stored securely. According to the general knowledge of one skilled in the art, the middle portion 106 and the rear portion 134 of the vehicle 100 may include the above-stated parts and/or other parts.

FIG. 2 shows a display assembly 200 according to an embodiment of the present disclosure coupled to the dashboard of the vehicle 100. The display assembly 200 may be configured to display the surrounding environment of the vehicle 100. The display assembly 200 may be communicatively coupled to the image sensing devices 130, 132 such as cameras. In other words, the display assembly 200 may be configured to receive images or videos from the image sensing devices 130, 132. It may be understood by the person skilled in the art that the display assembly 200 may also be arranged anywhere inside of the vehicle 100 such as A-pillar, B-pillar, C-pillar, inside of the doors 116, 118, 120, 122, back of the seats 108, 110, and a top ceiling of the vehicle 100. According to an embodiment, the image sensing devices 130, 132 capture the surrounding environment of the vehicle 100 and the captured images or videos are shown via the display assembly 200 to the occupant/s seated inside the vehicle 100.

In an embodiment, a first image sensing device 130 and a second image sensing device 132 may be adapted on the left side mirror assembly 124 and the right side mirror assembly 126 respectively. It may also be understood that the image sensing devices 130, 132 may be adapted to any exterior components of the vehicle 100 such as front bumper 150 or rear bumper 160 and are in particular arranged on opposite sides of the vehicle 100.

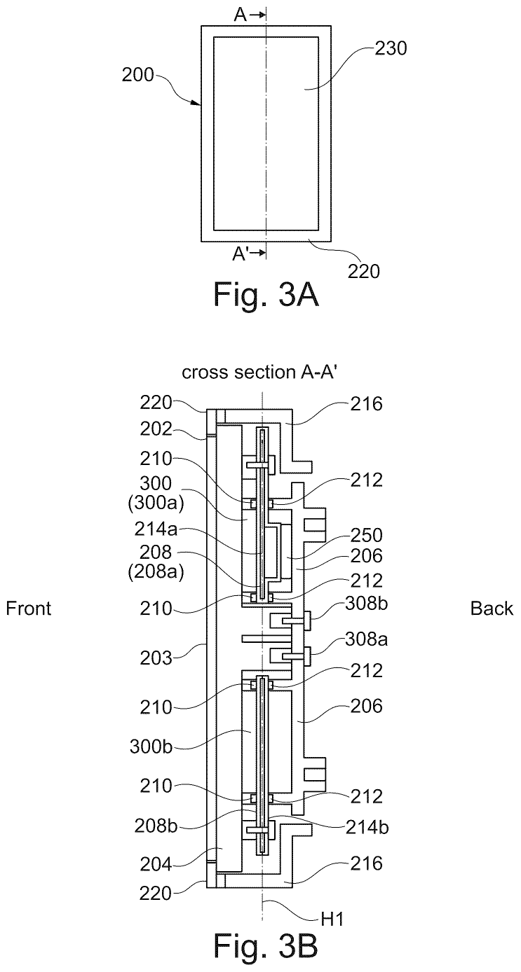

FIG. 3A shows the display assembly 200, which may be an active matrix liquid crystal display, such as a thin-film field-effect transistor (TFT) type, or a light emitting diode (LED) type display. In an embodiment, the display assembly 200 may be adapted to function as an infotainment system, or a global positioning system (GPS) device.

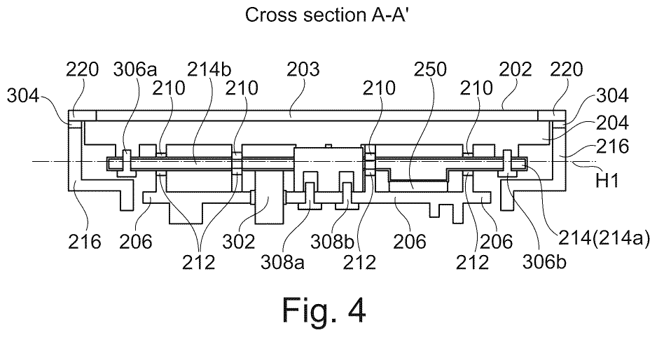

FIG. 3B and FIG. 4 each show a cross sectional view along the line A-A′ as depicted in FIG. 3A. The display assembly 200 comprises a display unit 202, a back light cover 204 coupled to the display unit 202, and a display holder 206 removably attached to the back light cover 204, wherein the display holder 206 may act as a display adapter. The display assembly 200 further comprises at least one printed circuit (PCB) 214, 214a, 214b. The at least one PCB 214 may also include or rather carry at least one control unit 208, 208a, 208b. The at least one PCB 214, 214a, 214b may further comprise a first PCB 214a and a second PCB 214b. The at least one control unit 208, 208a, 208b may comprise a first control unit 208a and a second control unit 208b. Both the control units 208a and 208b are communicatively coupled to each other, and to the display unit 202. These control units 208a and 208b and/or PCBs 214a, 214b may also be configured to act as a display driver and help the display unit 202 to display the images or videos from the data received from the image sensing devices 130, 132.

Further, the display unit 202 comprises a glass cover 203 to cover back lights such as LEDs or TFTs (not shown). The back lights are configured to provide videos or images to a vehicle occupant through the glass cover 203. The display unit 202 may comprise a panel 220. The back light cover 204 may be coupled to the display unit 202 via the panel 220. The display unit 202 may also act as an interface to the vehicle occupant. The display unit 202 may comprise a touch screen or pad acting as an HMI interface or input device to the display assembly 200. The back light cover 204 at least partially covers the back lights (not shown) of the display unit 202 from the back side.

In an embodiment, the back light cover 204 may be configured to provide one or more accommodation portions 300, 300a, 300b. The accommodation portion 300, 300a, 300b may comprise a first accommodation portion 300a and a second accommodation portion 300b. The first accommodation portion 300a and the second accommodation portion 300b may be separated by a partition. The first accommodation portion 300a and the second accommodation portion 300b are provided on the backside of the back light cover 204. The first accommodation portion 300a and the second accommodation portion 300b are positioned substantially lateral to each other to reduce overall thickness of the display assembly 200. For example, the first and second accommodation portion 300a, 300b are placed laterally to each other in a horizontal plane H1 to reduce overall thickness of the display assembly 200.

In an embodiment, the at least one control unit 208, 208a, 208b may be configured to be accommodated inside the accommodation portion 300, 300a, 300b. In an embodiment, the first accommodation portion 300a may accommodate the first control unit 208a. Similarly, the second accommodation portion 300b may accommodate the second control unit 208b.

In an embodiment, at least one control unit 208, 208a, 208b is disposed on at least one PCB 214, 214a, 214b. In an embodiment, at least one PCB 214, 214a, 214b is sandwiched between the back light cover 204 and the display holder 206. In turn, at least one control unit 208, 208a, 208b is sandwiched between the back light cover 204 and the display holder 206.

In another embodiment of the present disclosure, the first and second control units 208a, 208b are disposed on a single PCB 214. In still another embodiment, the first and second control units 208a, 208b are disposed on multiple PCBs 214, 214a, 214b. Each PCB 214, 214a, 214b is secured to the back light cover 204 by fasteners 306a, 306b inside the accommodation portion 300, 300a, 300b. It may be understood by the person skilled in the art that the at least one PCB 214, 214a, 214b may be secured by different ways, but not limited to, such as screwing, clamping, riveting, glueing or taping.

In the context of the present disclosure, the term “control unit” refers to one or more of various processing devices, such as a coprocessor, a microprocessor, a controller, a digital signal processor (DSP), a processing circuitry with or without an accompanying DSP, or various other processing devices including integrated circuits such as, for example, an application specific integrated circuit (ASIC), a field programmable gate array (FPGA), a microcontroller unit (MCU). a hardware accelerator, a special-purpose computer chip, integrated circuits, and the like. In an embodiment, the control unit 208 may be a driver for display image on the display unit 202.

The display holder 206 may be configured to mount the display assembly 200 to the vehicle 100 or a component of the vehicle 100. For example, the display holder 206 may be configured with a bracket on the backside to latch the display assembly 200 with the A-pillar, B-pillar or the ceiling of the vehicle 100. In another example, the display holder 206 may be arranged on the dashboard of the vehicle 100, as indicated in FIG. 2.

From the front side, the display holder 206 may be removably attached to the back light cover 204. In an embodiment, the display holder 206 may be removably attached to the back light cover 204 via fasteners 308a, 308b. It is also understood by the person skilled in the art that the display holder 206 may also be coupled to the back light unit 204 via an adhesive such as glue or tape or any other mechanism such as clamping or riveting. In an embodiment, the display holder 206 and the back light cover 204 are configured such that they form a closed enclosure to accommodate the control unit 208 and/or the electronic components including the control unit 208 disposed on the PCB 214. This closed enclosure acts as a Faraday cage for the control unit 208 and/or other electronic components. More details related to this will be disclosed below.

In an embodiment, the back light cover 204 and the display holder 206 are made of an electrically conductive material and made by a die casting process. The die casting process may be a metal casting process that involves feeding molten ferrous or nonferrous metals or alloys into dies or molds under high pressure and at adequate or high speed to rapidly create molded products of a specific or desired shape or dimensions. For example, the materials used in die casting are alloys of aluminum, magnesium and zinc.

The display assembly 200 further comprises a heat sink 250, as shown in FIGS. 3B and 4. The heat sink 250 may be disposed between the control unit 208 and the display holder 206. The heat sink 250 helps in dissipating the heat generated from the PCB 214 and/or the control unit 208 to the outside environment. In an embodiment, the heat sink 250 may include heat sink pads or paste. In another embodiment, the heat sink 250 may include an active or a passive type of heat sink. In still another embodiment, the heat sink 250 may be made up of a conductive material such as aluminum or copper. The display assembly 200 may be configured such that the heat sink 250 remain in contact with the display holder 206. In such a scenario, the display holder 206 being conductive in nature may also function as a heat dissipation unit. This is an added advantage of the current design where the display holder 206 also works as an EMC shield and the heat dissipation unit.

The display assembly 200 according to the embodiment of FIGS. 3B and 4 furthermore comprises a first EMC sealing unit 210 disposed between the unit 208 and the back light cover 204 and a second EMC sealing unit 212 disposed between the control unit 208 and the display holder 206. In an embodiment, the display holder 206 and the back light cover 204 are configured such that they form a closed enclosure to accommodate the control unit 208 and/or the PCB 214. This closed enclosure ensures EMC sealing of the control units 208 and/or the electronic components disposed on the PCB 214. The enclosure herein adapted as a Faraday cage where the control unit 208 and/or the electronic components disposed on the PCB 214 are shielded from all the external electrical and magnetic radiation. The first EMC sealing unit 210 and the second EMC sealing unit 212 further ensure that electromagnetic radiation does not leak outside of this enclosure or vice versa. It is well known that the Faraday cage is used to reduce the electromagnetic radiation coming out from an electronic assembly. It is also well known that the Faraday cage is an enclosure used to block electromagnetic fields.

In an embodiment, in the present disclosure, the display assembly 200 is further configured to at least partially shield electromagnetic radiation generated in the first accommodation portion 300a from reaching the second accommodation portion 300b; and at least partially shield electromagnetic radiation generated in the second accommodation portion 300b from reaching the first accommodation portion 300a.

In an embodiment, the at least two EMC sealing units 210, 212 are conductive in nature. For example, the at least two EMC sealing units 210, 212 are made up from copper, aluminum or their alloys. In another embodiment, the at least two EMC sealing units 210, 212 are formed in the display assembly 200 using a Form-in-Place (FIP) technology. The FIP technology is referred to as dispensing a liquid or form sealing element onto a metal or plastic parts before assembly of the device. In FIP technology, the sealing element is dispensed as a liquid or form, such that it fits precisely to the part's form or shape, regardless of the imperfections present on the surface. This results in a reliable EMC seal and durability for the display assembly 200. In an embodiment, FIP sealing units are dispensed using well known Computer Numerical Control (CNC) machines. In the context of the present disclosure, CNC may be referred to as a manufacturing method that automates the control, movement and precision of machine tools using preprogrammed computer software, which is embedded inside the tools. Further, the FIP process is so precise that surfaces less than one millimeter wide may still receive FIP sealing element application. The FIP sealing units are cost-effective, accurate, and possess an easy sealant solution, particularly in cases where a very small, narrow or complex sealing is required. In still another embodiment, the at least two EMC sealing units 210, 212 are formed using any one of a printing process, a CNC machining process or a combination thereof.

Referring to FIG. 4, a connector 302 may be connected to the second PCB 214b to provide data or electrical connection from the vehicle 100 (in particular a battery of the vehicle) to the display assembly 200. The connector 302 may also be connected to the first PCB 214a depending on the design of the display assembly 200. In an embodiment, a hole may be provided in a housing 216 to get a cable of the connector 302 to the outside. Further, between the housing 216 and the panel 220 a connection may be achieved via a sealing glue, an adhesive tape 304 or the like.

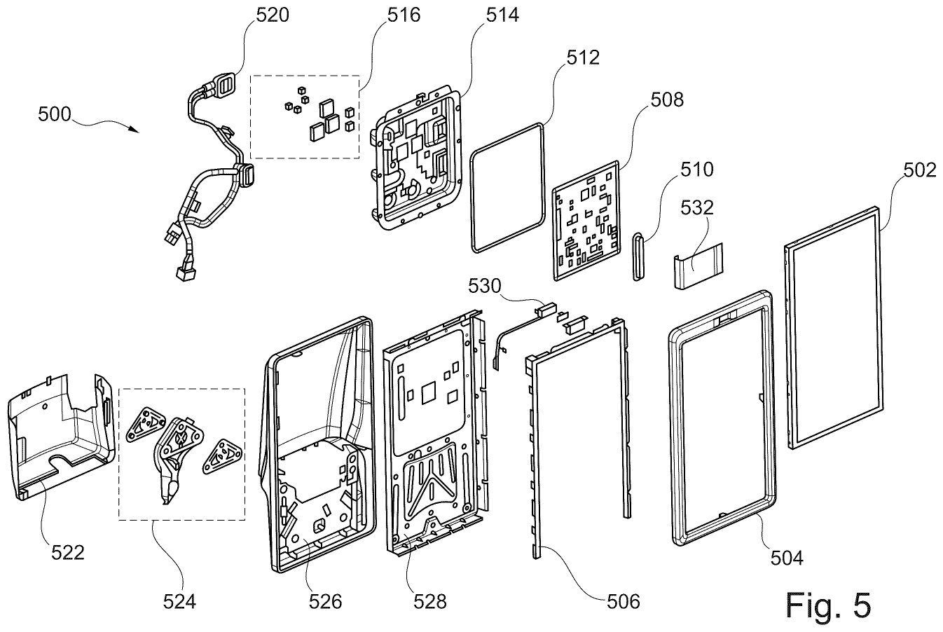

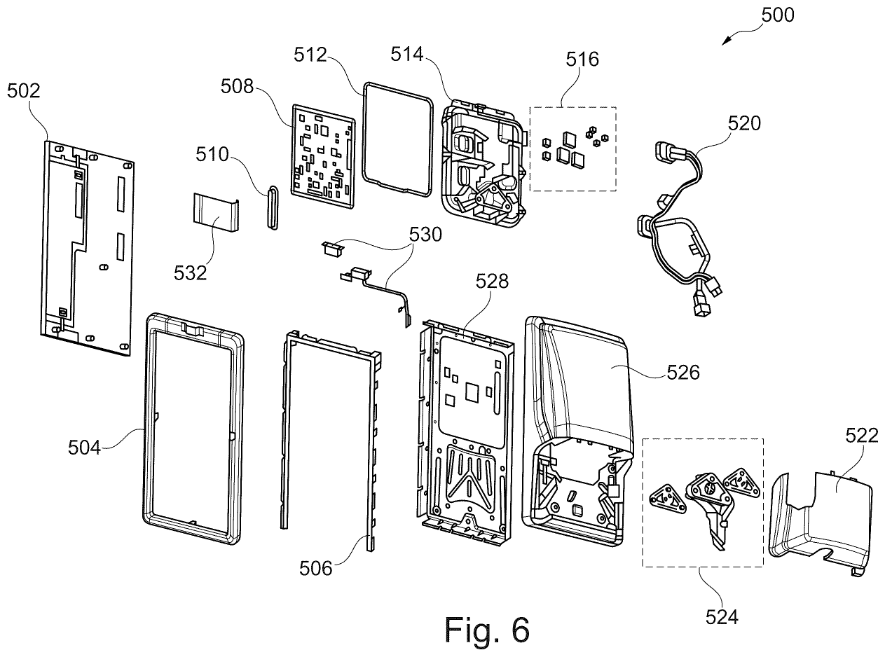

Referring to FIGS. 5 and 6, another embodiment of a display unit 500 is shown in exploded views. FIG. 5 shows the exploded view from the front side of the display unit 500. FIG. 6 shows the exploded view from the back side of the display unit 500. The display unit 500 comprises a display panel 502, a bezel 504, an adhesive tape 506, a flat cable 532, a flat cable grommet 510, a light sensor assembly 530, an ECU 508, heat sinks 516, an ECU box 514, a display attachment sheet 528, a display housing 526, at least one isolation washer 524, a display holder cover 522, an EMC sealing unit 512 and a display wire harness 520. The display panel 502 may be partially enclosed by the bezel 504 from the top, wherein the display panel 502 is attached with the bezel 504 with the help of the adhesive tape 506. The display attachment sheet 528 provides the support to the display panel 502. The ECU 508 may be supported by the ECU box 514 and the ECU box 514 may be coupled to the display holder cover 522 from the back side. The display holder cover 522 is adapted to be attached with a vehicle component (not shown) from a back portion of the display unit 500. The light sensor assembly 530 may be configured to be attached with the display panel 502. The heat sinks 516 may be disposed at the back surface of the ECU box 514 to dissipate heat to an outside environment. The heat sinks 516 may be a passive type of a heat sink. The EMC sealing unit 512 may be configured to electromagnetically seal the ECU 508. The EMC sealing unit 512 may be configured with the ECU box 514 using the Form-in-Place (FIP) technology.

The principle and mode of operation of this invention have been explained and illustrated in its preferred embodiment. However, it must be understood that this invention may be practiced otherwise than as specifically explained and illustrated without departing from its spirit or scope.

### REFERENCE SIGN LIST

100 vehicle
102 front portion
104 wheel
106 middle portion of the vehicle
108 driver seat
110 passenger seat
112 driver
114 passenger
116 front left side door
118 front right side door
120 back left side door
122 back right side door
124 left side mirror assembly
126 right side mirror assembly
130 image sensing device
132 image sensing device
134 rear portion
136 tail light assembly
138 boot space
150 front bumper
160 rear bumper
200 display assembly
202 display unit
203 glass cover
204 back light cover
206 display holder
208 control unit
208a first control unit
208b second control unit
210 first EMC sealing unit
212 second EMC sealing unit
214 PCB
214a first PCB
214b second PCB
216 housing
220 panel
250 heat sink
300 accommodation portion
300a first accommodation portion
300b second accommodation portion
302 connector
304 adhesive tape
306a fastener
306b fastener
308a fastener
308a fastener
500 display unit
502 display panel
504 bezel
506 adhesive tape 506
508 ECU
510 flat cable grommet
512 sealing unit
514 ECU box
516 heat sinks
520 wire harness
522 display holder cover
524 isolation washer
526 display housing
528 display attachment sheet
530 light sensor assembly
532 flat cable
A-A′ cross section line
H1 horizontal plane

What is claimed is:

1. A display assembly for a vehicle, the display assembly comprising:
at least one display unit;
at least one back light cover coupled to the display unit;
at least one display holder configured to mount the display assembly to the vehicle;
at least one printed circuit board (PCB); and
at least one first electromagnetic coupling (EMC) sealing unit disposed between the
PCB and the back light cover, and/or at least one second EMC sealing unit disposed between the PCB and the display holder.

2. The display assembly of claim 1, wherein the display holder is removably attached to the back light cover, and/or the display holder provides an EMC shield unit, and/or the display holder is conductive and/or provides a heat dissipation unit.

3. The display assembly of claim 1, wherein the PCB is sandwiched between the back light cover and the display holder, and/or at least one control unit is disposed on the PCB.

4. The display assembly of claim 3, wherein the control unit is sandwiched between the back light cover and the display holder.

5. The display assembly of claim 1, wherein at least one heat sink (250) is disposed between the PCB and the display holder.

6. The display assembly of claim 5, wherein the heat sink comprises at least one heat sink pad, a heat sink paste, and/or a conductive material.

7. The display assembly of claim 6, wherein the heat sink is an active heat sink and/or passive type of heat sink.

8. The display assembly of claim 6 wherein the conductive material is one of aluminum or copper.

9. The display assembly of claim 1, wherein the display holder and the back light cover are adapted to form an at least partly closed or a completely closed enclosure accommodating at least partly the control unit and/or the PCB, and/or the back light cover is configured to provide at least one accommodation portion for the control unit.

10. The display assembly of claim 9, wherein the enclosure provides an EMC sealing of the control unit and/or electronic components disposed on the PCB and/or the PCB, and/or the enclosure provides a Faraday cage shielding the control unit and/or the electronic components disposed on the PCB and/or the PCB from at least a part of or all the external electrical and magnetic radiation, and/or the first EMC sealing unit and the second EMC sealing unit ensure that at least a part or all of electromagnetic radiation does not leak outside of the enclosure or inside the enclosure.

11. The display assembly of claim 1, wherein the at least one PCB is a first PCB and a second PCB, the display assembly further comprising:
a first control unit and a second control unit; and
a first accommodation portion and a second accommodation portion, wherein the first accommodation portion accommodates the first PCB and/or the first control unit, and the second accommodation portion accommodates the second PCB and/or the second control unit.

12. The display assembly of claim 11, wherein the first accommodation portion and the second accommodation portion are positioned substantially laterally to each other, and/or the first control unit and the second control unit are positioned substantially laterally to each other and/or in a horizontal plane, and/or the first PCB and the second PCB are positioned substantially laterally to each other and/or in a horizontal plane.

13. The display assembly of any one of the claim 11, wherein electromagnetic radiation generated in the first accommodation portion is at least partially shielded from reaching the second accommodation portion, and/or electromagnetic radiation generated in the second accommodation portion is at least partially shielded from reaching the first accommodation portion.

14. The display assembly of claim 1, wherein the back light cover and/or the display holder comprise an electrically conductive material and/or are made by a die casting process.

15. The display assembly of claim 1, wherein the first EMC sealing unit and/or the second EMC sealing unit is/are conductive, and/or the first EMC sealing unit and/or the second EMC sealing unit is/are formed in the display assembly using a form-in-place technology, and/or the first EMC sealing unit and/or the second EMC sealing unit is/are formed in a dispensing process using a printing process, a Computer Numerical Control (CNC) machining process or a combination thereof.

16. The display assembly of claim 1, wherein the display unit comprises a panel and/or a glass cover.

17. The display assembly of claim 1, further comprising a housing to at least partially encase the display unit, the back light cover, and the PCB.

18. The display assembly of claim 17, wherein a sealing glue and/or adhesive tape is arranged between the housing and the display unit.

19. The display assembly of claim 17, wherein at least one connector is provided to be connected to the PCB to provide data and/or electrical connection from the vehicle and/or a battery of the vehicle to the display assembly.

20. The display assembly of claim 19, wherein at least one hole is provided in the housing to get a cable of the connector to the outside of the display assembly.
